(19) United States
(12) Patent Application Publication
(10) Pub. No.: US 2026/0134898 A1
(43) Pub. Date: May 14, 2026

(54) MEMORY BUFFERS

(71) Applicants: George Vergis, Portland, OR (US); Todd Andrew Hinck, Arlington, MA (US); James Alexander McCall, Portland, OR (US); Xiang Li, Portland, OR (US); Saravanan Sethuraman, Portland, OR (US)

(72) Inventors: George Vergis, Portland, OR (US); Todd Andrew Hinck, Arlington, MA (US); James Alexander McCall, Portland, OR (US); Xiang Li, Portland, OR (US); Saravanan Sethuraman, Portland, OR (US)

(21) Appl. No.: 19/429,733

(22) Filed: Dec. 22, 2025

Related U.S. Application Data
(60) Provisional application No. 63/865,055, filed on Aug. 15, 2025.

(51) Int. Cl. G11C 7/10; G06F 13/16

(52) U.S. Cl. CPC G11C 7/1075; G06F 13/1673

(57) ABSTRACT

Systems, apparatus, articles of manufacture, and methods are disclosed to implement memory buffers. An example an integrated circuit includes a plurality of data buffers including a plurality of data ports; a registered clock driver; and a multiplexer to selectively couple to a first one of the plurality of data ports or a second one of the plurality of data ports.

### RELATED APPLICATION

This patent claims the benefit of U.S. Provisional Patent Application No. 63/865,055 , which was filed on Aug. 15, 2025. U.S. Provisional Patent Application No. 63/865,055 is hereby incorporated herein by reference in its entirety. Priority to U.S. Provisional Patent Application No. 63/865,055 is hereby claimed.

### BACKGROUND

Computing devices include several types of memory and storage for short term and long-term storage of data. One such type of memory is random access memory (RAM). One type of RAM is double data rate (DDR) memory, which is a type of synchronous dynamic random-access memory (SDRAM) that can transfer data on both the rising and falling edges of a clock signal, effectively doubling the data transfer rate compared to single data rate SDRAM. This technology is used in a wide range of devices, including PCs, servers, and mobile devices, and has evolved through several generations (DDR2, DDR3, DDR4, and DDR5), each offering improvements in speed, efficiency, and capacity.

### BRIEF DESCRIPTION OF THE DRAWINGS

FIG. 1 is a schematic diagram of an example implementation of a memory including an integrated memory buffer (IMB) as disclosed herein.

FIG. 2 is a schematic map of an example implementation of the IMB of FIG. 1.

FIG. 3 is an illustration of an example implementation of a multiplexer of the IMB of FIG. 1.

FIGS. 4-7 are schematic illustrations of the memory of FIG. 1 including example interconnections.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Memory modules include a plurality of data buffers (DBs) and a registered clock driver (RCD). The DBs carry data payloads between a memory controller (e.g., a memory controller of a host) and memory cells (e.g., dynamic random-access memory (DRAM) cells) on the memory module, ensuring matched impedance and minimal skew across all lanes. The RCD delivers a clean, low-skew clock signal by buffering and registering the clock before fan-out to the memory interface.

While the DBs and RCD have typically been implemented as independent elements, an integrated memory buffer (IMB) that packages a plurality of DBs and an RCD is disclosed herein. By combining the DBs and RCD into a signal package, the amount of physical space occupied by the DBs, RCD, and signal lines can be reduced. For example, the DDR 6 (DDR6) memory form factor is a smaller form factor than DDR 5 (DDR5) memory. A DDR6 dual-inline memory module (DIMM) has side dimensions of approximately 74.50 millimeters (mm) by 31.25 mm, which is smaller than DDR5 memory. Utilizing IMBs (e.g., two IMBs per side of the DIMM) reduces the amount of physical space consumed and reduces the number of package pins needed as compared to discrete DB and RCD implementations to fit on the DDR6 DIMM. For example, a DIMM in accordance with the memory buffering disclosed herein may include four IMBs and 10 DRAM modules (e.g., x24 DRAM modules) for 1 U of fully buffered memory. In such an example, a power management integrated circuit (PMIC) and associated components (e.g., inductors and capacitors) can be placed on each side of the DIMM. In some examples, the IMB includes a DQ multiplexer that multiplexes connection to the DRAM in time (e.g., round robin multiplexing) to allow two ranks of DRAM to operate in parallel, effectively doubling the data throughput. In some examples, the backside IMB supports x240 data and the front side IMB supports x120 data from connectors of the DIMM.

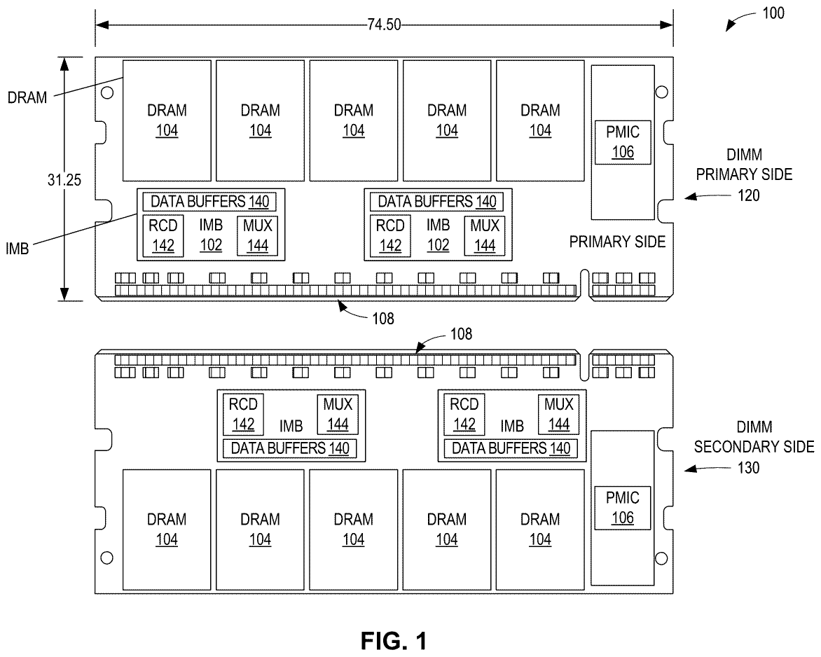

FIG. 1 is a schematic diagram of an example implementation of a memory 100 including integrated memory buffer (IMB) 102 as disclosed herein.

The example memory 100 includes four IMBs 102, ten DRAM modules 104, two PMICs 106, and a plurality of connector pins 108. The example memory 100 includes two sides: a first side 120 and a second side 130 (e.g., a front side and a back side, a primary side and a secondary side, etc.). The example components are split between half on the first side 120 and half on the second side 130. Alternatively, any other layout may be utilized (e.g., more or fewer components depending on a DIMM side and any other division of components between the first side 120 and the second side 130).

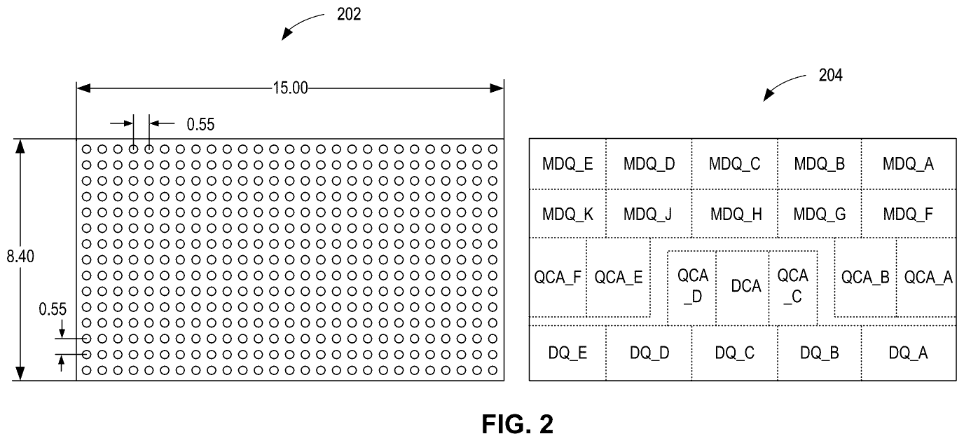

The example IMB 102 includes data buffers 140, a registered clock driver (RCD) 142, and a multiplexer 144. For example, the IMB 102 may be a circuit board having components mounted on it, a package, chip, an integrated circuit, etc. An example implementation of the floorplan for the example IMB is illustrated in FIG. 2. The data buffers 140 of the illustrated example are implemented by application-specific integrated circuits (ASICs) but may be implemented by any other type of data storage circuit. The example RCD 142 is also implemented by an ASIC but may be implemented by any other type of circuit such as a logic circuit. The multiplexer 144 selectively couples ranks of memory to allow two ranks of DRAM to operate in parallel.

The example DRAM 104 is implemented by a plurality of DRAM chips. Alternatively, the DRAM 104 may be implemented by any other type of memory circuitry.

The example PMIC 106 manages power supplied to the components of the memory 100. While the illustrated example includes a PMIC 106 for each side of the memory 100, a single PMIC 106 for the entire memory 100 may be utilized and/or multiple PMIC 106 may be included on a side. Alternatively, power management could be controlled by a device that is not included on the memory 100.

The example memory 100 includes a plurality of connector pins 108 on the first side 120 and the second side 130. The connector pins 108 allow the memory 100 to be communicatively coupled with a host (e.g., via a socket on a motherboard). The example connector pins 108 include two levels of pins (e.g., an upper row and a lower row) to provide for a sufficient number of pins on a narrower DDR6 memory module (as compared to a DDR5 memory module). Alternatively, any other connector pin arrangement may be utilized (e.g., one side of pins, one row of pins, etc.).

In operation, a host reads/writes data from/to the memory 100 via signals sent and received on the connector pins 108, which are coupled to the plurality of IMB 102. Further description of the connections of the IMB to the connectors 108 and the DRAM 104 is described in conjunction with FIG. 2.

FIG. 2 is a schematic map of an example implementation of the IMB 102 of FIG. 1. FIG. 2 includes an illustration of a footprint 202 for the IMB 102. In particular, the footprint illustrates an example dimension of 15.00 mm by 8.40 mm with a pin spacing of 0.55 mm, for a pin layout of 15×27. FIG. 2 also includes a floorplan map 204. As illustrated in FIG. 2, the floorplan includes two rows of five MDQ ports (for a total of 10 MDQ ports), a row of six QCA ports around a DCA port, and a row of five DQ ports. According to the illustrated example, each DCA port includes five command/address (CA) pins, two chip select (CS) pins, and one clock (CLK) pair. While the example IMB 102 of FIG. 2 includes a particular number and arrangement of ports and dimensions that are designed to minimize the distance between the MDQ ports and the DRAM 140 and the distance between the DQ ports and the connector pins 108, other arrangements may be implemented. For example, the relative arrangement of the ports may be changed depending on the relative placement of the IMB 102, the DRAM 104, and the connector pins 108. Similarly, the relative dimensions of the form factor 202 may be selected to be compatible with the layout of the memory 100 (e.g., a shorter and wider layout (e.g., fewer but wider rows)) may be utilized if the space between the DRAM 104 and the connector pins 108 is reduced as compared to the illustrated examples. According to the illustrated example, each IMB 102 is implemented as a package that matches the illustrated form factor 202. Alternatively, the IMB 102 may be implemented as two or more components/packages.

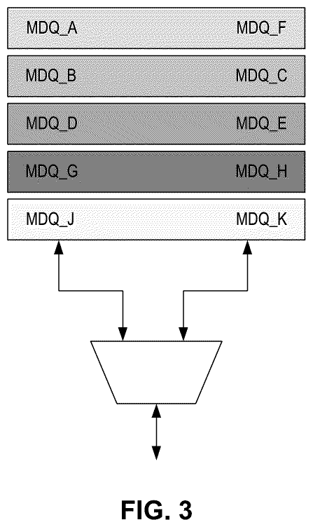

FIG. 3 is an illustration of an example implementation of a multiplexer 144 of the IMB 102 of FIG. 1. The example multiplexer multiplexes two MDQ ports to selectively couple to a single communication port (e.g., a single DQ port). According to the illustrated example, the multiplexer 144 selectively couples among MDQ ports that are adjacent to each other (e.g., MDQ_A and MDQ_F, MDQ_B and MDQ_C, MDQ_D and MDQ_E, MDQ_G and MDQ_H, and MDQ_J and MDQ_K). Alternatively, other groupings may be utilized. Furthermore, while a two-to-one multiplexer 144 is utilized in the illustrated example, other types of multiplexers may be utilized (e.g., 3-to-1, 4-to-1, etc.).

The example multiplexer 144 is controlled by a host to select which pairs of ports are activated. Alternatively, the memory 100 may include a processor, controller, control logic, etc. that can control the multiplexer 144. While the example IMB 100 includes a multiplexer, any other type of selection logic or device may be utilized to selectively couple ports.

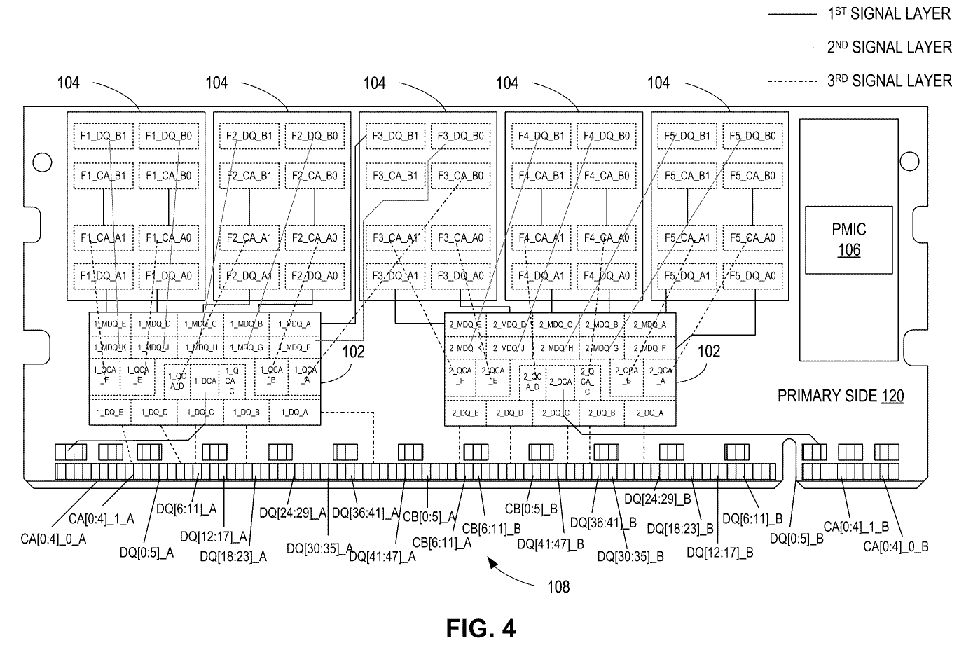

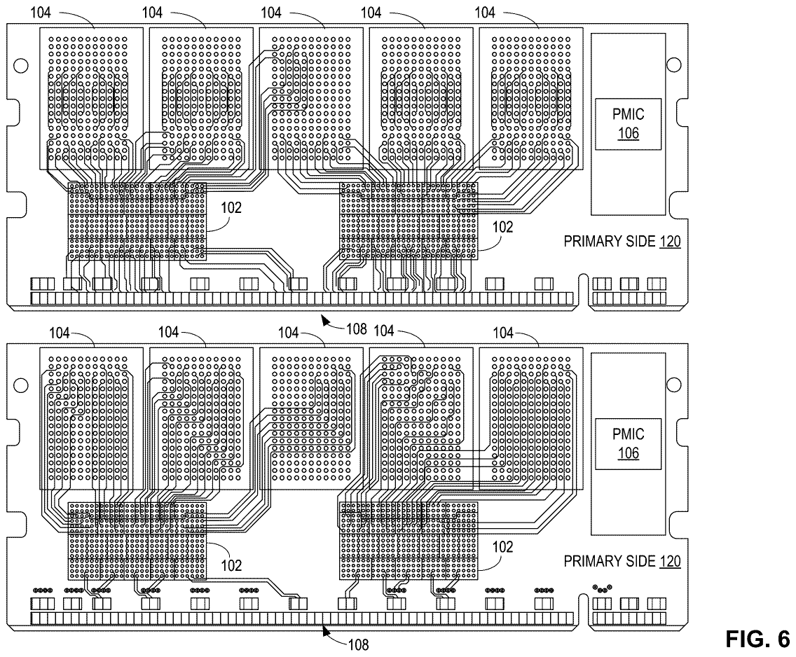

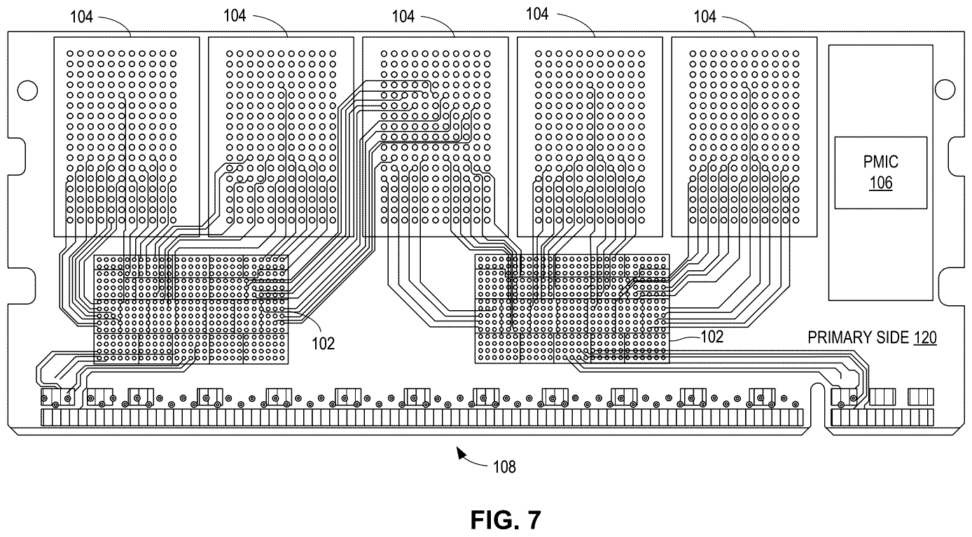

FIGS. 4-7 are schematic illustrations of the memory 100 of FIG. 1 including example interconnections among the connector pins 108, the IMBs 102, and the DRAM 104.

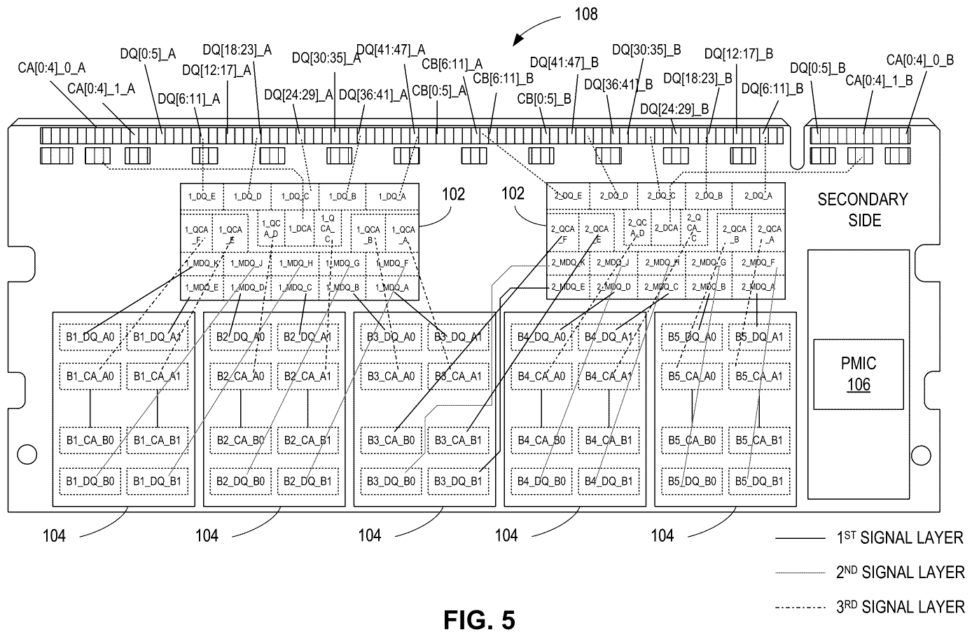

As illustrated in FIGS. 4 and 5, the IMB 102 includes eight MDQ ports that are respectively connected to four DQ ports of a first DRAM 104 and four DQ ports of a second DRAM 104. The IMB 102 additionally includes another two MDQ ports respectively connected to two DQ ports of a third DRAM 104. The third DRAM 104 includes an additional two DQ ports that are connected to two MDQ ports of a second IMB 102, which also includes another eight MDQ ports that are connected respectively to the DQ ports of a fourth and fifth DRAM modules 104. The example port connections facilitates connection of five DRAM modules 104, while fully utilizing the MDQ ports of two IMB 102. Such an arrangement allows a single IMB 102 package to be designed and reused. Alternatively, two or more different IMB 102 layouts may be utilized. For example, each side of the memory 100 could include two IMB 102 that include eight MDQ ports and one IMB 102 that includes four MDQ ports. In another design, one IMB 102 with four MDQ ports could be coupled to each of the DRAM modules 104 (e.g., for five total IMB 102). The size of the IMB 102 has been selected to correspond to the number of DQ ports of the DRAM 104. In other examples, the number of MDQ ports could be increased or decreased to correspond to the number of DQ ports of the DRAM 104 that is implemented.

As illustrated in FIGS. 4-7, the connections among the components of the memory 100 may be implemented in multiple layers (e.g., three layers in the illustrated example) to facilitate routing. While three layers are illustrated with particular routing paths, other numbers of layers and other routing paths may be selected. For example, the connections could be implemented on a single layer, two layers, more than three layers, etc. In some implementations, a routing path and layout of the elements in the IMB 102 is selected to minimize the length of connection paths.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that integrate memory data buffers and a registered clock driver to reduce the physical space for implementing such components in memory modules. Implementations of the proposed integrated memory buffer may utilize two integrated member buffers per side of a memory module to reduce the physical space utilized as compared with discrete data buffers and registered clock drivers. In such implementations, a proposed multiplexer approach may increase communication speed by time multiplexing memory ranks in parallel. In some implementations, the reduced physical space and speed increases may be implemented without affecting power and thermal density beyond suitable limits.

Example methods, apparatus, systems, and articles of manufacture to implement memory buffers are disclosed herein. Further examples and combinations thereof include the following:

Example 1 includes an integrated circuit comprising a plurality of data buffers including a plurality of data ports, a registered clock driver, and a multiplexer to selectively couple to a first one of the plurality of data ports or a second one of the plurality of data ports.

Example 2 includes the integrated circuit of example 1, wherein the plurality of data ports are memory data queue (MDQ) ports.

Example 3 includes the integrated circuit of example 2, wherein the plurality of data buffers includes a plurality of data bus ports (DQ).

Example 4 includes the apparatus of any one or more of examples 1-3, wherein the plurality of data ports includes a plurality of data bus ports (DQ), a plurality of memory data queue (MDQ) ports, a plurality of quad command/address (QCA) ports, and a data capture/align (DCA) port.

Example 5 includes the apparatus of any one or more of examples 1-4, wherein the plurality of data ports includes five data bus ports (DQ), ten memory data queue (MDQ) ports, six quad command/address (QCA) ports, and a data capture/align (DCA) port.

Example 6 includes the integrated circuit of example 5, further including a plurality of chip select pins.

Example 7 includes the integrated circuit of example 6, further including a clock (CLK) pair.

Example 8 includes a memory circuit comprising a circuit board, a plurality of memory modules mounted to the circuit board, and an integrated circuit including a plurality of data buffers and a registered clock driver coupled to at least one of the plurality of memory modules.

Example 9 includes the memory circuit of example 8, wherein the integrated circuit is a first integrated circuit and further including a second integrated circuit including a second plurality of data buffers and a second registered clock driver coupled to a second at least one of the plurality of memory modules.

Example 10 includes the memory circuit of example 9, wherein at least one of the memory modules is coupled to both the first integrated circuit and the second integrated circuit.

Example 11 includes the apparatus of any one or more of examples 9-10, wherein the first integrated circuit includes a first memory data queue (MDQ) port coupled to a data bus port (DQ) of first memory module of the plurality of memory modules and a second MDQ coupled to a first DQ of a second memory module of the plurality of memory modules.

Example 12 includes the memory circuit of example 11, wherein the second integrated circuit includes a first MDQ port coupled to a DQ of a third memory module of the plurality of memory modules and a second MDQ port coupled to a second DQ of the second memory module of the plurality of memory modules.

Example 13 includes the memory circuit of example 12, further including a fourth memory module, and a fifth memory module.

Example 14 includes the apparatus of any one or more of examples 8-13, wherein the plurality of data buffers includes a memory data queue (MDQ) port coupled to a data bus port (DQ) of a memory module of the plurality of memory modules.

Example 15 includes the apparatus of any one or more of examples 8-14, wherein the integrated circuit and the plurality of memory modules are mounted to a first side of the circuit board and the memory circuit further includes a second plurality of memory modules mounted to a second side of the circuit board, and a second integrated circuit including a second plurality of data buffers and a second registered clock driver coupled to at least one of the plurality of memory modules, the second integrated circuit mounted to the second side of the circuit board.

Example 16 includes the apparatus of any one or more of examples 8-15, wherein a memory module of the plurality of memory modules includes four 24-bit sub-channels.

Example 17 includes a dual in-line memory module comprising a power management integrated circuit, a plurality of interconnect pins, a plurality of memory circuits, and an integrated memory buffer (IMB) circuit including a plurality of data buffers and a registered clock driver, the IMB coupled to at least one of the plurality of memory circuits and at least one of the plurality of interconnect pins.

Example 18 includes the dual in-line memory module of example 17, wherein the dual in-line memory module is a dual data rate memory module.

Example 19 includes the dual in-line memory module of example 18, wherein the dual in-line memory module is a dual data rate 6 memory module.

Example 20 includes the apparatus of any one or more of examples 17-19, further including three layers, wherein the first layer includes a first plurality of connections between the IMB and at least one of the plurality of memory modules, the second layer includes a second plurality of connections between the IMB and at least one of the plurality of memory modules, and the third layer includes a third plurality of connections between the IMB and at least one of the plurality of memory modules.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit comprising:
a plurality of data buffers including a plurality of data ports;
a registered clock driver; and
a multiplexer to selectively couple to a first one of the plurality of data ports or a second one of the plurality of data ports.

2. The integrated circuit of claim 1, wherein the plurality of data ports are memory data queue (MDQ) ports.

3. The integrated circuit of claim 2, wherein the plurality of data buffers includes a plurality of data bus ports (DQ).

4. The integrated circuit of claim 1, wherein the plurality of data ports includes:
a plurality of data bus ports (DQ);
a plurality of memory data queue (MDQ) ports;
a plurality of quad command/address (QCA) ports; and
a data capture/align (DCA) port.

5. The integrated circuit of claim 1, wherein the plurality of data ports includes:
five data bus ports (DQ);
ten memory data queue (MDQ) ports;
six quad command/address (QCA) ports; and
a data capture/align (DCA) port.

6. The integrated circuit of claim 5, further including a plurality of chip select pins.

7. The integrated circuit of claim 6, further including a clock (CLK) pair.

8. A memory circuit comprising:
a circuit board;
a plurality of memory modules mounted to the circuit board; and
an integrated circuit including a plurality of data buffers and a registered clock driver coupled to at least one of the plurality of memory modules.

9. The memory circuit of claim 8, wherein the integrated circuit is a first integrated circuit and further including a second integrated circuit including a second plurality of data buffers and a second registered clock driver coupled to a second at least one of the plurality of memory modules.

10. The memory circuit of claim 9, wherein at least one of the memory modules is coupled to both the first integrated circuit and the second integrated circuit.

11. The memory circuit of claim 9, wherein the first integrated circuit includes a first memory data queue (MDQ) port coupled to a data bus port (DQ) of first memory module of the plurality of memory modules and a second MDQ coupled to a first DQ of a second memory module of the plurality of memory modules.

12. The memory circuit of claim 11, wherein the second integrated circuit includes a first MDQ port coupled to a DQ of a third memory module of the plurality of memory modules and a second MDQ port coupled to a second DQ of the second memory module of the plurality of memory modules.

13. The memory circuit of claim 12, further including:
a fourth memory module; and
a fifth memory module.

14. The memory circuit of claim 8, wherein the plurality of data buffers includes a memory data queue (MDQ) port coupled to a data bus port (DQ) of a memory module of the plurality of memory modules.

15. The memory circuit of claim 8, wherein the integrated circuit and the plurality of memory modules are mounted to a first side of the circuit board and the memory circuit further includes:
a second plurality of memory modules mounted to a second side of the circuit board; and
a second integrated circuit including a second plurality of data buffers and a second registered clock driver coupled to at least one of the plurality of memory modules, the second integrated circuit mounted to the second side of the circuit board.

16. The memory circuit of claim 8, wherein a memory module of the plurality of memory modules includes four 24-bit sub-channels.

17. A dual in-line memory module comprising:
a power management integrated circuit;
a plurality of interconnect pins;
a plurality of memory circuits; and
an integrated memory buffer (IMB) circuit including a plurality of data buffers and a registered clock driver, the IMB coupled to at least one of the plurality of memory circuits and at least one of the plurality of interconnect pins.

18. The dual in-line memory module of claim 17, wherein the dual in-line memory module is a dual data rate memory module.

19. The dual in-line memory module of claim 18, wherein the dual in-line memory module is a dual data rate 6 memory module.

20. The dual in-line memory module of claim 17, further including three layers, wherein the first layer includes a first plurality of connections between the IMB and at least one of the plurality of memory modules, the second layer includes a second plurality of connections between the IMB and at least one of the plurality of memory modules, and the third layer includes a third plurality of connections between the IMB and at least one of the plurality of memory modules.
